(19) United States
(12) Patent Application Publication
(10) Pub. No.: US 2009/0235987 A1
(43) Pub. Date: Sep. 24, 2009

(54) Chemical Treatments to Enhance Photovoltaic Performance of CIGS

(75) Inventors: Masud AKHTAR, Lawrenceville, NJ (US); Alan E. Delahoy, Rocky Hill, NJ (US)

Correspondence Address: STERNE, KESSLER, GOLDSTEIN & FOX P.L.L.C., 1100 NEW YORK AVENUE, N.W., WASHINGTON, DC, 20005, US

(73) Assignee: EPV Solar, Inc., Robbinsville, NJ (US)

(21) Appl. No.: 12/410,297

(22) Filed: Mar. 24, 2009

Related U.S. Application Data
(60) Provisional application No. 61/007,550, filed on Mar. 24, 2008.

(51) Int. Cl. H01L 31/0272; H01L 31/00; B08B 3/08; B08B 3/10; C01B 19/00; H01L 21/02

(52) U.S. Cl. 136/262; 134/19; 134/2; 423/508; 438/73; 257/E21.347; 257/E31.008

(57) ABSTRACT

The present invention provides method of treating semiconductor surfaces (e.g., CIGS) using various solvents (including ionic solvents and eutectics), and methods preparing photovoltaic cells comprising treated CIGS materials.

### CROSS-REFERENCE TO RELATED APPLICATIONS

This application claims the benefit of U.S. Provisional Patent Application No. 61/007,550, which was converted to a provisional application on Oct. 21, 2008, from U.S. Nonprovisional application Ser. No. 12/053,793, filed Mar. 24, 2008, the disclosures of each of which are incorporated by reference herein in their entireties.

### BACKGROUND OF THE INVENTION

1. Field of the Invention

This invention relates generally to processes of chemically cleaning and passivating defects often present at compound semiconductor surfaces, and more particularly, to processes that are useful to treat polycrystalline chalcopyrite surfaces of solar cells in order to enhance their photovoltaic device properties.

2. Background Art

Chalcopyrite ternary thin films of copper-indium-diselenide (CuInSe₂) and copper-indium-gallium-diselenide (CuIn_{1-X}Ga_{X}Se₂), both of which are generically referred to as Cu(In,Ga)Se₂, CIGS, or simply CIS, have become the subject of considerable interest and study for semiconductor devices in recent years. Sulfur can also be, and sometimes is, combined with, or substituted for, selenium. The compound is sometimes also referred to even more generally as Cu(In,Ga)(Se,S)₂, so as to encompass all of these possible combinations. These materials are also referred to as I-III-VI₂ devices according to their constituent elemental groups. These materials are of particular interest for photovoltaic devices or solar cell absorber applications. For photovoltaic applications, the p-type CIGS layer is combined with an n-type semiconductor thin film like a CdS layer to form a p-n heterojunction CdS/CIGS device.

The preparation of CIGS, copper indium-gallium diselenide absorber material, for example, Cu(In_{0.7}Ga_{0.3})Se₂, requires temperatures around 500° C. and a vacuum environment. During CIGS preparation, in an attempt to meet stoichiometric, thermal and atmospheric requirements, the formation of trace amounts of binary compositions consisting of selenides, oxides, and carbonates etc., can occur. These trace amounts of impurity phases can exist at the nascent CIGS surfaces. The existence of such impurities at the CIGS surfaces greatly impairs photovoltaic conversion efficiencies of solar cells comprising these materials.

### SUMMARY OF THE INVENTION

Therefore, there is a need to chemically clean the CIGS surfaces and passivate the defects inherently present in the compound semiconductor CIGS material prior to the incorporation of CIGS thin films into a solar cell embodiment.

In one embodiment, the present invention provides methods of treating a CIGS material. The methods suitably comprise contacting the CIGS material with an ionic solvent comprising S- or Se-containing compounds and heating the CIGS material. Suitably, the CIGS material is contacted with an ionic solvent comprising thiourea, for example, thiourea in the range of about 0.01M to about 1.00 M. In exemplary embodiments, the heating comprises heating the CIGS material to a temperature in the range of about 30° Celsius to about 85° Celsius, for example, heating the CIGS material for about 10 minutes to about 80 minutes. In suitable embodiments, the CIGS material is contacted with a 0.6 M thiourea solution, and heated to a temperature of about 60° Celsius for about 60 minutes. The methods of the present invention suitably dissolve impurity phases of binary oxides and selenides of copper, indium and gallium to improve photovoltaic properties of a solar cell comprising the treated CIGS material. In exemplary embodiments, the CIGS material to be treated is disposed on an electrically conducting substrate.

The present invention also provides methods of treating a CIGS material, comprising contacting the CIGS material with a eutectic solvent that comprises thiourea and choline chloride at a 2:1 molar ratio (thiourea:choline chloride), and heating the CIGS material. Suitably, the eutectic solvent comprises 2M thiourea and 1M choline chloride, and the CIGS material is heated at about 80° Celsius for about 10 minutes to about 60 minutes. As described herein, the methods of the present invention suitably dissolve impurity phases of binary oxides and selenides of copper, indium and gallium to improve photovoltaic properties of a solar cell comprising the prepared CIGS material. In exemplary embodiments, the CIGS material to be treated is disposed on an electrically conducting substrate.

In exemplary embodiments, the CIGS material is contacted with an aqueous solution of 2M thiourea and 1M choline chloride, and heated at about 25° Celsius for about 10 minutes to about 60 minutes. In further embodiments, the CIGS material in an aqueous solution of 0.6M thiourea and 0.3M choline chloride, and the heating comprises heating at about 60° Celsius for about 10 to about 60 minutes.

The present invention also provides CIGS materials treated by any of the methods of the present invention.

In further embodiments, the present invention provides methods of preparing a CIGS solar cell. The methods suitably comprise providing a CIGS film deposited on an electrically conducting substrate. The CIGS material is contacted with a solvent comprising S- or Se-containing compounds. The CIGS material is heated. The CIGS material is prepared for inclusion in a solar cell, and a front contact is disposed on the CIGS material to form the solar cell.

Suitably, a CIGS semiconductor film is disposed on a glass substrate comprising an electrically conducting substrate. In exemplary embodiments, the CIGS material is contacted with an ionic solvent comprising thiourea, for example, thiourea in the range of about 0.01M to about 1.00 M. Suitably, the CIGS material is heated to a temperature in the range of about 30° Celsius to about 85° Celsius, suitably, for about 10 minutes to about 80 minutes. In exemplary embodiments, the CIGS material is contacted with 0.6 M thiourea, and heated a temperature of about 60° Celsius for about 60 minutes. As described herein, the methods of the present invention suitably dissolve impurity phases of binary oxides and selenides of copper, indium and gallium.

In exemplary embodiments, the CIGS material is contacted with a eutectic solvent comprising thiourea and choline chloride at a 2:1 molar ratio (thiourea:choline chloride), for example, a eutectic solvent that comprises 2M thiourea and 1M choline chloride. Suitably, the CIGS material is heated at about 80° Celsius for about 10 minutes to about 60 minutes. In exemplary embodiments, the CIGS material is contacted with an aqueous solution of 2M thiourea and 1M choline chloride, and heated at about 25° Celsius for about 10 minutes to about 60 minutes. In further embodiments, CIGS material is contacted with an aqueous solution of 0.6M thiourea and 0.3M choline chloride, and heated at about 60° Celsius for about 10 to about 60 minutes.

Suitably, preparing the CIGS material for inclusion in a photovoltaic cell comprises washing and then drying the CIGS material. The methods can further comprise disposing a buffer layer on the CIGS material prior to disposing the front contact. Exemplary buffer layers comprise a layer of CdS, and exemplary front contacts comprise a transparent conductive oxide, such as ZnO.

The present invention also provides CIGS solar cells prepared by the various methods described herein.

The present invention also provides methods for improvement of CIGS solar cells.

Another embodiment of the invention provides improvements to methods for making CIGS solar cells by extracting secondary phases like CuₓSe from the semiconductor with continuous processes using safe reagents, while simultaneously removing trace amounts of binary oxides and other selenide related impurity compositions form CIGS thin film surfaces.

In further embodiments, the present invention provides improvements to methods for making CIGS solar cells by increasing sheet resistance of CIGS thin films.

The present invention also provides improvements to methods of making CIGS solar cells to enhance solar cell conversion efficiencies by reducing the surface defect density of states and improving bulk material semiconductor properties.

The present invention also provides methods of forming a CIGS solar cell. Suitably, a CIGS material is deposited on an electrically conducting substrate. The CIGS material is heated in an aqueous solution of thiourea. Active defects present in the CIGS material are compensated for and the photovoltaic properties of the CIGS solar cell are improved.

In further embodiments, the present invention provides methods of forming a CIGS solar cell. A CIGS material is deposited on an electrically conducting substrate. The CIGS material is heated in a eutectic solvent (e.g., a eutectic in a molar ratio of 2:1, for example, a solution of 2M thiourea and 1 M choline chloride, or an aqueous eutectic of 0.6M thiourea and 0.3M choline chloride, heated at about 60° C. for about 10-60 minutes). Impurity phases of binary oxides and selenides of copper, indium and gallium are dissolved out and the photovoltaic properties of the CIGS solar cell are improved.

In a further embodiment, the present invention provides methods of forming a CIGS solar cell, comprising providing a CIGS film deposited on an electrically conducting substrate, and treating the CIGS film with S or Se containing compounds dissolved in an ionic solvent (e.g., a eutectic solvent), which behaves like a low cost, nontoxic ionic solvent.

Further embodiments, features, and advantages of the invention, as well as the structure and operation of the various embodiments of the invention are described in detail below with reference to accompanying drawings.

### BRIEF DESCRIPTION OF THE DRAWINGS

The invention is described with reference to the accompanying drawings. In the drawings, like reference numbers indicate identical or functionally similar elements. The drawing in which an element first appears is indicated by the left-most digit in the corresponding reference number.

FIG. 1 is a schematic illustration of a CIGS solar cell produced by the methods of the present invention.

FIG. 2 is a flowchart of a method of treating a CIGS material in accordance with an embodiment of the present invention.

FIG. 3(a) is a graph of current density verses voltage of CIGS solar cells that have an area of 0.5 cm².

FIG. 3(b) is a graph comparing quantum efficiencies of two CIGS solar cells.

### DETAILED DESCRIPTION

In embodiments, the present invention provides methods of treating CIGS material that are suitable for use in CIGS solar cells. The methods provide improved methods for making CIGS materials by extracting secondary phases like CuₓSe from the semiconductor, utilizing safe reagents, while also removing trace amounts of binary oxides and other selenide related impurity compositions from the CIGS materials.

In one embodiment, the present invention provides methods of treating a CIGS material. The treatment methods comprise contacting the CIGS material with an ionic solvent comprising S- or Se-containing compounds. As used herein, the term “contacting” includes various methods of introducing an ionic solvent to the CIGS material, such as spraying, applying, coating, disposing, depositing, dipping, layering, painting, covering, etc. As used herein, the term “ionic solvent” refers to solvents in which ion-ion interactions occur resulting in the dissolution of a solute in the solvent. Suitably, the CIGS material is disposed on an electrically conducting substrate, such as a conductive layer on a glass substrate. The CIGS material is then heated. In exemplary embodiments, the CIGS material can be heated in bath of the ionic solvent (i.e., heated in the solvent), or in other embodiments, the CIGS material can be contacted with the solvent, and then the CIGS material can be heated. In still further embodiments, the CIGS material can be heated, and then contacted with the solvent, or the CIGS material can be contacted with a heated solvent.

As used herein “CIGS” refers to semiconductor materials comprising copper-indium-diselenide (CuInSe₂) and/or copper-indium-gallium-diselenide (CuIn_{1-X}Ga_{X}Se₂), both of which are generically referred to as Cu(In,Ga)Se₂, CIGS, or simply CIS herein and in the art.

In exemplary embodiments, the ionic solvent for treatment of the CIGS materials comprises an aqueous solution of thiourea. In solution, thiourea exists in tautomeric forms as:

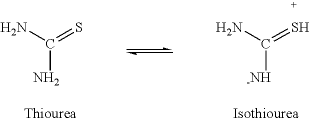

In solution, besides the presence of coordinating S atoms, there are amino-, imino-, and thiol-groups interacting with CIGS material. Trace amounts of thiourea molecules can coordinate bond or react through sulfur with metal atoms present in CIGS. While —SH, and —NH groups can pacify the anionic and cationic defect density states, the —NH2 groups are able to remove the oxide and carbonate type impurities from the CIGS surfaces.

In exemplary embodiments, the concentration of thiourea is in the range of about 0.01M to about 1.00 M, suitably about 0.1M to about 1.00M, about 0.3M to about 0.9M, about 0.4M to about 0.8M, about 0.5M to about 0.7M or about 0.6M. Suitably, the thiourea is prepared by diluting in deionized water.

Suitably, the CIGS material is heated to a temperature in the range of about 30° Celsius to about 85° Celsius while in contact with the ionic solvent comprising S- or Se-containing compounds. In exemplary embodiments, the CIGS material is heated to a temperature of about 40° C. to about 80° C., about 50° C. to about 70° C., or about 60° C. The heating in the ionic solvent generally occurs for about 10 minutes to about 80 minutes, suitably about 20 minutes to about 70 minutes, about 30 minutes to about 70 minutes, about 40 minutes to about 70 minutes, about 50 minutes to about 70 minutes, or about 60 minutes. In exemplary embodiments, the CIGS material is heated to a temperature of about 60° Celsius in a 0.6 M thiourea solution for about 60 minutes.

Treating the CIGS material with the ionic solvent removes impurity phases of binary oxides and selenides of copper, indium and gallium from the surface of the CIGS material. Removal of these impurity phases improves photovoltaic properties of a solar cell comprising the prepared CIGS material.

Another embodiment of the present invention utilizes the solvent properties of ionic liquids to treat CIGS materials. Ionic liquids are a broad class of solvents consisting of poorly coordinating pairs of cations and anions. These reagents possess unusual solvent properties due the high concentration of anions present in them. A wide range of such liquids are available which include imidazolinium and pyridinium salts. Some properties of these solvents are described in Published International Patent Application No. WO 2004/003120, incorporated herein by reference in its entirety. These ionic liquids are versatile reagents for surface improvement for compound semiconductors. A particular class of related reagents of importance for CIGS device improvement are nontoxic eutectic solvents. These eutectic solvents behave like ionic liquids but consist of very low cost and safe chemicals. These reagents consist of quaternary ammonium cations complexed with hydrogen bonding anions and are more fully described in Novel Solvent Properties of Choline Chloride/Urea Mixtures, Andrew P. Abbot and David L. Davies, Chemical Communications, P70, (2003 ); European Patent No. 1324979, to Abbot, et al., and Chemical and Engineering News, Michael Freemantle, P36 (2005), the disclosures of each of which are incorporated by reference herein.

Eutectic solvents for use in the practice of the present invention possess ionic liquid like properties allowing them to dissolve several metal oxides, and salts which are normally difficult to dissolve in ordinary solvents. These eutectic solvents are useful for the cleaning of CIGS surfaces, as described herein. In exemplary embodiments, a eutectic (EU) for use in the practice of the present invention comprises thiourea, (2HN)₂C═S, (abbreviated herein as TU; melting point of 175° C.) and choline chloride, HOCH₂CH₂N(CH₃)₃Cl, (abbreviated herein as ChCl; melting point of 302° C.), This eutectic has a freezing point of about 69° C. when mixed at a molar ratio of 2:1, for example, 2 M thiourea and 1 M choline chloride. The eutectic for use in the practice of the present invention can be in the form of a neat liquid (undiluted) or in solution with various solvents, such as water.

Thus, in further embodiments, the CIGS material is contacted with a eutectic solvent that comprises thiourea and choline chloride. The CIGS material is then heated.

Methods of contacting the CIGS material with the eutectic solvent, and methods and orders of contacting and heating are described throughout. As noted herein, the CIGS material can be heated in a bath of the solvent (i.e., heated in the solvent), or in other embodiments, the CIGS material can be contacted with the solvent, and then the CIGS material can be heated. In still further embodiments, the CIGS material can be heated, and then contacted with the solvent, or the CIGS material can be contacted with a heated solvent.

Suitably, the thiourea and choline chloride are at a molar ratio in the range of about 4:1 to about 0.1:1 (thiourea:choline chloride). More suitably, the thiourea and choline chloride are at molar ratio in the range of 3:1 to 1:1, and most suitably, the thiourea and choline chloride are at 2:1 molar ratio. The concentration of thiourea in the eutectic is suitably in the range of about 0.1 M to about 10 M, or about 1 M to about 10 M, about 1 M to about 8 M, about 1 M to about 6 M, about 1 M to about 4 M, about 1 M to about 3 M, or about 2M. The concentration of choline chloride in the eutectic is suitably in the range of about 0.1 M to about 5 M, about 0.5 M to about 5 M, about 0.5 M to about 3 M, about 0.5 M to about 2 M, or about 1 M. In exemplary embodiments, the eutectic solvent comprises about 2M thiourea and about 1M choline chloride.

Exemplary temperatures and heating times are described throughout. Suitably, the CIGS material is heated in a eutectic solvent that comprises thiourea and choline chloride at about 60° C. to about 90° C., suitably about 80° C., for about 10 minutes to about 60 minutes. For example, the CIGS material can be heated in an aqueous solution of 0.6 M thiourea and 0.3 M choline chloride at about 60° Celsius for about 10 minutes to about 60 minutes.

In further embodiments, the heating can be to a temperature at or around room temperature. For example, the CIGS material can be heated in the ionic solution to temperature of about 20° C. to about 30° C., or about 23° C. to 28° C., or about 25° C. For example, the methods of the present invention can comprise heating the CIGS material in an aqueous solution of 2M thiourea and 1M choline chloride at about 25° Celsius for about 10 minutes to about 60 minutes.

The present invention also provides CIGS materials prepared by the various treatment methods described herein.

By removing impurity phases of binary oxides and selenides of copper, indium and gallium from the surface of the CIGS material, the sheet resistance of a CIGS thin film increases. In addition, photovoltaic modules prepared using CIGS materials treated with the methods of the present invention have been found to exhibit enhanced solar cell conversion efficiencies, by having reduced surface defect density states and improved bulk material semiconductor properties.

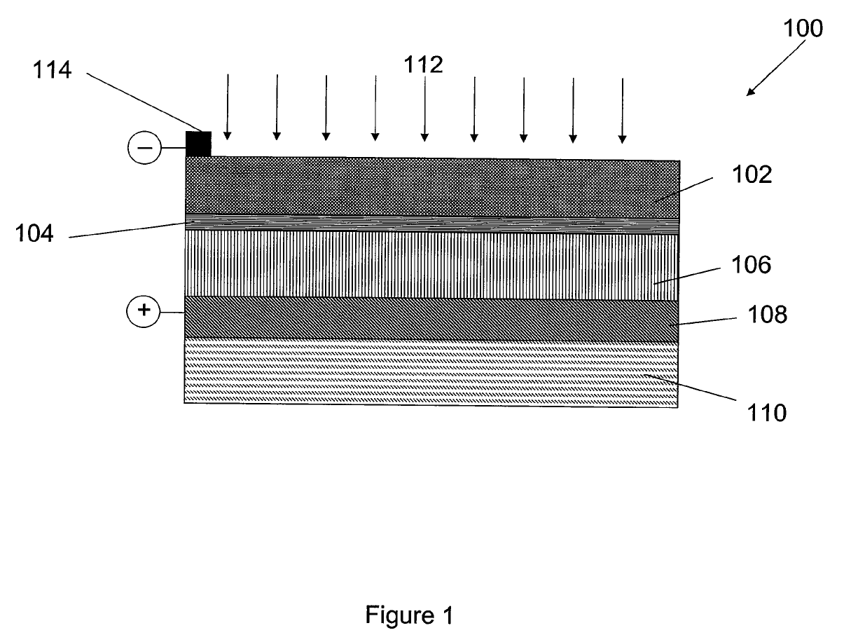

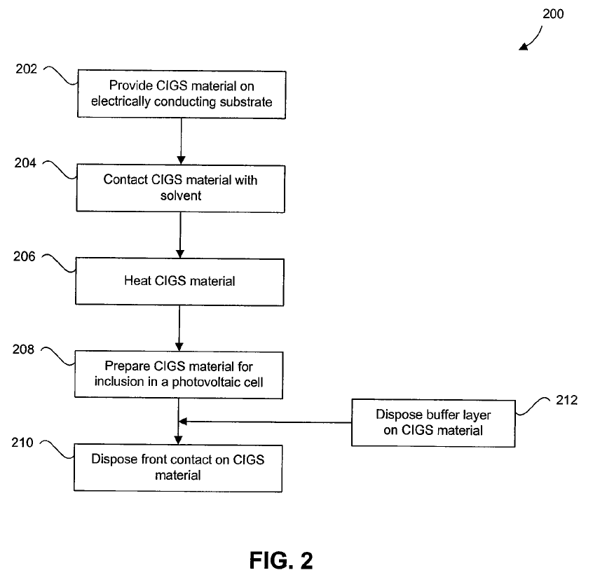

In further embodiments, the present invention provides methods of preparing a CIGS solar cell 100 (solar cell, solar module, photvoltaic (PV) cell and photovoltaic module are used interchangeably throughout). As shown in flowchart 200 of FIG. 2, with reference to FIG. 1, in suitable embodiments, the methods comprise providing a CIGS material 106 deposited on an electrically conducting substrate 108 in 202. In 204 of flowchart 200, the CIGS material 106 is contacted with an ionic solvent, and then in 206, the CIGS material is heated. As described throughout, suitably the ionic solvent comprises S- or Se-containing compounds. Exemplary ionic solvents comprise thiourea, suitably thiourea at a concentration in the range of about 0.01 M to about 1.00 M. In further embodiments, the ionic solution can comprise a eutectic solvent, including eutectic solvents that comprise thiourea and choline chloride, suitably at a 2:1 molar ratio (thiourea:choline chloride). In exemplary embodiments, the CIGS material can be heated in a bath of the solvent (i.e., heated in the solvent), or in other embodiments, the CIGS material can be contacted with the solvent, and then the CIGS material can be heated. In still further embodiments, the CIGS material can be heated, and then contacted with the solvent, or the CIGS material can be contacted with a heated solvent.

In 208, the CIGS material is prepared for inclusion in a photovoltaic cell, for example photovoltaic cell 100. For example, the CIGS material is washed and then dried, before inclusion in a solar cell. In 210 of flowchart 200, a front contact 102 is disposed on the CIGS material, thereby forming a photovoltaic cell 100.

In exemplary embodiments, the CIGS semiconductor film is provided on a glass substrate 110 comprising electrically conducting substrate 108. Methods for preparing a glass substrate with an electrically conducting substrate are well known in the art and include various sputtering, chemical and physical deposition methods. In other embodiments, a glass substrate 110 with a pre-disposed electrically conducting substrate 108 can simply be purchased as a pre-manufactured unit.

As described herein, heating of the CIGS material with the ionic solvent is generally in range of about 30° Celsius to about 85° Celsius, and for 10 minutes to about 80 minutes. For example, the CIGS material can be heated to a temperature of about 60° Celsius in a 0.6 M thiourea solution for about 60 minutes.

In other embodiments, the CIGS material can be heated in a eutectic solvent that comprises thiourea and choline chloride, suitably at a 2:1 molar ratio (thiourea:choline chloride). For example, the CIGS material can be heated in a eutectic solvent that comprises 2M thiourea and 1M choline chloride, and suitably, at about 80° Celsius for about 10 minutes to about 60 minutes, or the CIGS material can be heated in an aqueous solution of 0.6M thiourea and 0.3M choline chloride at about 60° Celsius for about 10 to about 60 minutes. In still further embodiments, the CIGS material is heated in an aqueous solution of 2M thiourea and 1M choline chloride at about 25° Celsius for about 10 minutes to about 60 minutes.

As described throughout, treating the CIGS material according to the methods of the present invention dissolves impurity phases of binary oxides and selenides of copper, indium and gallium and repairs defects in the surface of the material. Removal of these impurity phases, and repair of defects helps to improve the efficiency of the CIGS materials when they are ultimately incorporated into a PV cell.

As shown in flowchart 200 of FIG. 2, the methods of the present invention can further comprise in 212 disposing a buffer layer 104 on the CIGS material prior to disposing the front contact 102. In exemplary embodiments, buffer layer 104 comprises a layer of CdS. Suitably, front contact 102 comprises a transparent conductive oxide, such as ZnO or SnO₂.

In further embodiments, the present invention provides CIGS solar cells prepared by the methods described herein. FIG. 1 is a schematic diagram of an exemplary CIGS solar cell structure that can be made with the methods of the present invention.

As illustrated in FIG. 1, a thin film solar cell 100 includes a substrate 110 that can be made of soda lime glass sheet, for example, a 3 mm thick soda lime glass sheet covered with an approximately 10 Å thick binder. A conductor film 108 is disposed on the substrate 110, and in suitable embodiments, is a Mo film with a thickness of about 2400 Å. Chalcopyrite semiconductors 106 are the disposed on the conductive substrate 108.

The semiconductors 106 can have a thickness of approximately 15,000 Å (1.5 μm). In one embodiment, the semiconductors 106 comprise a thin film of copper-indium-gallium-diselenide Cu(InₓGa₁₋ₓ)Se₂, where x ranges from 1 to approximately 0.6 (CIGS) with a two-probe resistance of generally about 100,000 ohm. The “two-probe” resistance is that measured by placing two metal probes on the surface of the CIGS, the CIGS having been coated onto a conducting substrate (e.g., molybdenum-coated glass). A buffer film 104 is suitably disposed on the CIGS material. The buffer film 104 can be CdS (or can comprise zinc or indium sulfides) and suitably has a thickness of about 500 Å. A transparent conductive oxide (TCO) (front contact) 102 can be made of about 50-1000 Å thick i-ZnO and about 2000 to 10,000 Å thick n-ZnO films, suitably with a sheet resistance of 5-50 ohm/square (ohm/sq), the n-ZnO thickness being chosen as appropriate for a solar cell or an interconnected module. Light enters the cell 100 from the top TCO film side 102. Also shown in FIG. 1 is electrical contact 114 that can be used to electrically connect a series of PV modules 100.

Physical vapor deposition can be used to deposit the CIGS film 106. In one embodiment, process heated source materials produce a flux of each of the desired constituents. Controlling the source temperature fixes the flux rate from each source. Various shuttering devices can also be used to modulate the effects of temperature control. Thus CIGS films of desired thickness can be deposited upon an electrically conducting substrate for the manufacture of the CIGS solar cell 100. The stoichiometry of the CIGS material is controlled by the deposition process. The other components of the device can be deposited by routine sputtering, chemical bath deposition techniques and the like.

In further embodiments, a number of CIGS films can be formed. The CIGS films can have thicknesses in the range of about 15,000-20,000 Å (1.5-2.0 μm), and can be deposited on, for example, 2 inch by 4 inch substrates, or any size substrate. The CIGS can then be treated in a solvent of the present invention in chemical baths. The chemical baths can include aqueous solutions of thiourea, (TU), at different concentrations as disclosed herein. For eutectic solvents, (EU), the chemical treatment baths can include neat EU (i.e., undiluted) as well as aqueous EU solutions comprising thiourea:choline chloride at a 2:1 molar ratio, for example, 2M thiourea:1M choline chloride i.e. 2M TU:1M ChCl.

The temperature and treatment times for the CIGS layers can be varied as described herein. CIGS layers are suitably rinsed in deionized water, air dried prior to inclusion in PV modules.

It will be readily apparent to one of ordinary skill in the relevant arts that other suitable modifications and adaptations to the methods and applications described herein can be made without departing from the scope of the invention or any embodiment thereof. Having now described the present invention in detail, the same will be more clearly understood by reference to the following examples, which are included herewith for purposes of illustration only and are not intended to be limiting of the invention.

### EXAMPLE 1

CIGS cells are treated by either A) immersion in a 0.6 M solution of thiourea at 60° C. for 60 minutes; or B) immersion in a solution of eutectic comprising 0.6M thiourea and 0.3M choline chloride at 60° C. for 60 minutes.

The CIGS substrates are then rinsed with deionized water and dipped in a chemical bath to deposit a 500 Å thick cadmium sulfide film on the CIGS. The chemical bath comprises 0.0015M cadmium sulfate, 2.25M ammonium hydroxide and 0.075M thiourea. The cadmium sulfide film is deposited over a period of 20 minutes at about 53-56° C. The CIGS substrate is then washed with deionized water, air dried and annealed at a temperature of about 150° C. in an oven for 30 minutes. The substrate is then ready for further processing into a solar cell.

### EXAMPLE 2

Photovoltaic devices prepared from CIGS batch number H103007 demonstrate the difference between untreated and thiourea treated substrates prior to complete device fabrication. Treatment parameters are provided in Table 1. The CIGS devices were characterized by standard current-voltage and quantum efficiency measurement techniques.

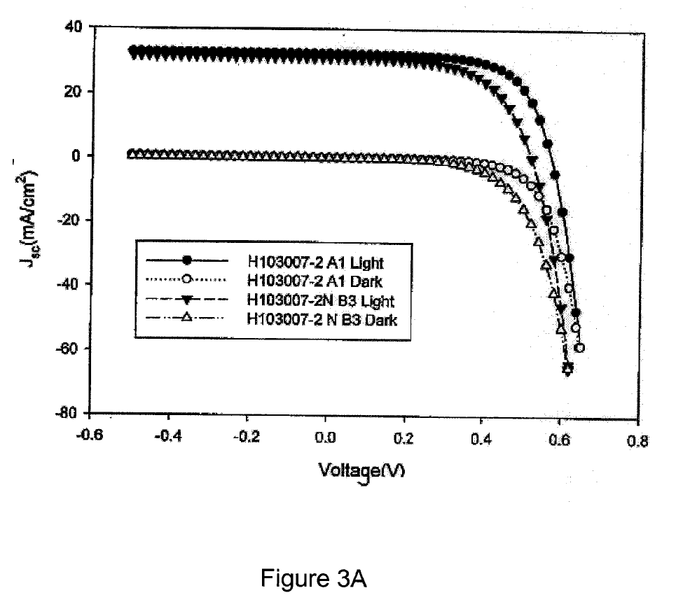

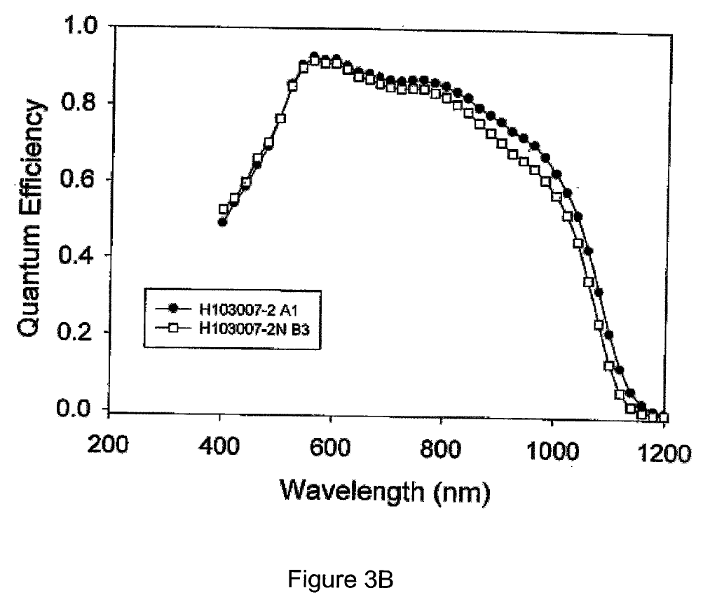

A comparison of two solar cell characteristics is illustrated in FIG. 3(a). For the treated cell, H103007-2, the Voc was 573.9 mV, the FF was 65.7%, the Jsc was 32.22 mA/cm², and the efficiency was 12.1%. For the untreated cell, H103007-2N, the Voc was 523.7 mV, the FF was 59.2%, the Jsc was 31.06 mA/cm², and the efficiency was 9.6%.

The device parameters for treated and untreated CIGS solar cells are listed in Table 1 for comparison.

TABLE 1
Solar Cell Improvement by TU Solution Treatment of CIGS Films.

| | | | | Jsc | |
|---|---|---|---|---|---|
| Sample No. | Treatment | Voc mV | FF % | mA/cm² | Eff % |
| H103007-1 | TU, 0.6M, | 565.8 | 66.4 | 31.8 | 11.9 |
| | 60° C., 60 min | | | | |
| H103007-1N | None | 548.2 | 63.1 | 31.86 | 11.0 |
| H103007-2A1 | TU, 0.6M, | 573.9 | 65.7 | 32.22 | 12.1 |
| | 60° C., 60 min | | | | |
| H103007-2NB3 | None | 523.7 | 59.2 | 31.06 | 9.6 |
| H103007-5 | TU, 0.6M, | 581.7 | 68.0 | 31.14 | 12.3 |
| | 60° C., 60 min | | | | |
| H103007-5N | None | 560.6 | 68.0 | 30.65 | 11.5 |

The thiourea treatment of CIGS results in higher device Voc, higher FF, and improved quantum efficiency as illustrated in FIG. 3(b). In FIG. 3(b), H103007-2 is treated, and H103007-2N is untreated. This enhances the overall solar cell efficiency by compensating for CIGS material defects present at CIGS film surfaces.

### EXAMPLE 3

In this example, an improvement in CIGS device efficiencies associated with TU treatment is illustrated in a different batch of CIGS.

TABLE 2

| | | | | Jsc | |
|---|---|---|---|---|---|
| Sample No. | Treatment | Voc mV | FF % | mA/cm² | Eff % |
| H010606-2A1 | TU, 0.6M, 60° C., | 582.6 | 71.99 | 30.14 | 12.64 |
| | 60 min | | | | |
| H010606-2B1 | TU, 0.6M, 60° C., | 576.5 | 70.8 | 30.99 | 12.65 |
| | 60 min | | | | |
| H010606-5A1 | TU, 0.6M, 60° C., | 571.4 | 72.98 | 30.4 | 12.68 |
| | 60 min | | | | |
| H010606-5B3 | TU, 0.6M, 60° C., | 561.7 | 72.65 | 29.95 | 12.22 |
| | 60 min | | | | |
| Average | | 573.05 | 72.11 | 30.37 | 12.55 |
| H010606-6A3 | None | 606.4 | 68.87 | 28.76 | 12.01 |
| H010606-3A1 | None | 563.3 | 69.83 | 29.1 | 11.45 |
| H010606-3B1 | None | 583.9 | 69.67 | 30.16 | 12.27 |
| H010606-3B2 | None | 562.6 | 70.17 | 30.29 | 11.96 |
| Average | | 579.05 | 69.64 | 29.58 | 11.92 |

### EXAMPLE 4

In this example, the effects of different concentrations of thiourea during different treatment times are shown for CIGS device properties in Table 3. Different concentrations of thiourea are capable of improving the device characteristics of CIGS samples.

TABLE 3

| | | Voc | | Jsc | |
|---|---|---|---|---|---|
| Sample No. | Treatment | mV | FF % | mA/cm² | Eff % |
| Z1698-11B | TU, 0.1M, 60° C., 60 min | 581.2 | 69.32 | 27.22 | 10.97 |
| Z169812C | TU, 0.6M, 60° C., 60 min | 598.1 | 62.96 | 26.91 | 10.13 |
| Z1565-5 | TU, 0.096M, 60° C., | 504.1 | 63.4 | 25.45 | 8.13 |
| | 60 min | | | | |
| Z1565-7 | TU, 0.6M, 60° C., 60 min | 506 | 64.2 | 26.32 | 8.55 |
| Z1702-11C | None | 541.8 | 47.38 | 24.24 | 6.22 |
| Z1702-5B | TU, 0.6M, 60° C., 60 min | 497.7 | 63.89 | 28.21 | 8.97 |
| Z1666-1-7 | None | 505.1 | 66.41 | 25.32 | 8.49 |
| Z1666-1-8 | TU, 0.13M, 60° C., 60 min | 541.6 | 68.49 | 25.36 | 9.41 |
| Z1666-2-14 | TU, 0.13M, 60° C., 90 min | 540.5 | 69.63 | 25.08 | 9.44 |
| Z1539-3 | TU, 1M, 85° C., 30 min | 564.5 | 53.6 | 22.58 | 6.83 |
| Z1539-11 | TU, 0.6M, 60° C., 60 min | 581.1 | 54.75 | 20.13 | 6.40 |

### EXAMPLE 5

In this example, comparative data consisting of CIGS film sheet resistance and CIGS elemental composition, determined by ICP-instrument, is given for (A) untreated and TU treated CIGS and (B) untreated and EU treated CIGS samples. The results are presented in Table 4a.

TABLE 4a

| | | Two-probe | % | % | % | % | Se/ | Cu/ | Ga/ | Ga/ | In/ |
|---|---|---|---|---|---|---|---|---|---|---|---|
| Sample No. | Treatment | Resistance Ω | Cu | Ga | In | Se | CIGS | (In + Ga) | (In + Ga) | Cu | Cu |
| H 111006-1 | None | 20 | 29 | 9 | 13 | 49 | 0.98 | 1.32 | 0.41 | 0.31 | 0.44 |
| H 111006-1A | TU 0.6M, | 200 | 25 | 10 | 14 | 51 | 1.04 | 1.03 | 0.42 | 0.41 | 0.57 |
| | 60° C., 60 min | | | | | | | | | | |
| H111006-4 | None | 20 | 30 | 10 | 12 | 48 | 0.94 | 1.34 | 0.43 | 0.32 | 0.42 |
| H111006-4A | EU, 80°, | 40,000 | 25 | 11 | 15 | 49 | 0.98 | 0.99 | 0.42 | 0.43 | 0.58 |
| | 60 min | | | | | | | | | | |

TABLE 4b

| | | Voc | FF | Jsc (QE) | Eff |
|---|---|---|---|---|---|
| Run # | Pretreatment | (mV) | (%) | (mA/cm²) | (%) |
| H111006- | TU | 255.1 | 28.2 | 1.95 | 0.10 |
| 1, 2, 3 | | | | | |
| H111006- | TU-EU | 355.7 | 50.4 | 19.9 | 3.60 |
| 4, 5, 6 | | | | | |

In this example, the percentage of Cu in CIGS samples decreased with TU and EU treatments. However, the two-probe resistance of CIGS increased from 20 to 200 ohm with TU and from 20 to 40,000 ohm with EU treatment. With eutectic treatment, the Cu/(In+Ga) ratio approached 0.99 confirming the overall cleaning of CIGS material by this reagent. For all four test samples, photovoltaic cell structures were constructed and tested. The cells constructed on substrates H111006-4,5,6, from run # H111006 were EU treated and showed an average cell efficiency of 3.6% (see Table 4b), while the cells from the remaining three test substrates (H111006-1,2,3) showed very little photovoltaic effect. It is apparent from these test results that the EU treatment is capable of extracting the generally present conducting phases in CIGS consisting of compounds like CuₓSe while at the same time enhancing the photovoltaic properties of CIGS material.

### EXAMPLE 6

In this example, samples of this preparation of CIGS were left in a laboratory atmosphere for five months. These test samples were converted into CIGS photovoltaic devices in one batch after different treatments. A comparison of device parameters is shown in Table 5 for untreated, TU and EU treated CIGS substrates.

TABLE 5

| | | Voc | | Jsc | |
|---|---|---|---|---|---|
| Sample No. | Treatment | mV | FF % | mA/cm² | Eff % |
| Z1797-7A | None | 571.3 | 36.05 | 23.21 | 4.8 |
| Z1797-11 | None | 551.2 | 37.62 | 22.47 | 4.7 |
| AVERAGE | | 561.25 | 36.84 | 22.84 | 4.72 |
| Z1797-8 | TU 0.6M, 60° C., 60 min | 570.6 | 56.24 | 29.36 | 9.4 |
| Z1797-9A | TU 0.6M, 60° C., 60 min | 564.9 | 58.99 | 29.28 | 9.8 |
| Z1797-10 | TU 0.6M, 60° C., 60 min | 570.7 | 54.42 | 29.4 | 9.1 |
| Z1797-11A | TU 0.6M, 60° C., 60 min | 563.6 | 61.13 | 29.91 | 10.3 |
| AVERAGE | | 567.45 | 57.70 | 29.49 | 9.63 |
| Z1797-7 | EU, 80° C., 30 min | 543.4 | 67.51 | 30.34 | 11.1 |
| Z1797-8A | EU, 80° C., 30 min | 565.5 | 69.4 | 30.19 | 11.8 |
| Z1797-9 | EU, 80° C., 30 min | 554 | 69.38 | 29.67 | 11.4 |
| AVERAGE | | 554.30 | 68.76 | 30.07 | 11.46 |

The untreated CIGS samples showed a very low conversion efficiency of average of 4.72% indicating that CIGS material had degraded in the ambient laboratory atmosphere. TU treatment of CIGS substantially improved the cell efficiency to an average of 9.63%. The EU (neat) treatment was beneficial for this batch in improving the cell quality by enhancing the device average efficiency to 11.46 %

### EXAMPLE 7

In this example, a CIGS panel with a thickness of 1.5 microns was fabricated and left in an ambient laboratory atmosphere for five months. Test samples of the panel were exposed to three different treatments. The test devices were measured. The results are in Table 6.

TABLE 6

| Sample No. | Treatment | Voc mV | FF % | Jsc mA/cm2 | Eff % |
|---|---|---|---|---|---|
| Z1973-41 | TU, 0.6M, 60° C., 60 min | 550.5 | 57.1 | 28.23 | 8.9 |
| Z1793-50 | TU, 0.6M, 60° C., 60 min | 557.4 | 60 | 29.31 | 9.8 |
| AVERAGE | | 554.0 | 58.6 | 28.8 | 9.3 |
| Z1793-42 | EU, (TU, 0.6M + ChCl | 543.7 | 68.5 | 29.87 | 11.1 |
| | 0.3M), 60° C., 60 min. | | | | |
| Z1793-44 | EU, (TU 0.6M + ChCl 0.3M), | 546.2 | 68.5 | 29.71 | 11.1 |
| | 60° C., 60 min. | | | | |
| Z1793-46 | EU, (TU 0.6M + ChCl 0.3M), | 537.7 | 68.2 | 29.58 | 10.8 |
| | 60° C., 60 min. | | | | |
| Z1793-48 | EU, (TU 0.6M + ChCl 0.3M), | 552.1 | 67.3 | 30.15 | 11.2 |
| | 60° C., 60 min.), | | | | |
| | 60° C., 60 min. | | | | |
| AVERAGE | | 544.9 | 68.1 | 29.8 | 11.1 |
| Z1793-35 | EU, 80° C., 20 min | 547.1 | 65.8 | 29.05 | 10.46 |
| 3-40 | EU, 80° C., 20 min. | 551.1 | 67.3 | 28.94 | 10.73 |
| AVERAGE | | 549.22 | 66.6 | 29.0 | 10.6 |

The comparison of device efficiencies illustrates that the CIGS treatment involving an aqueous eutectic solution, where TU (thiourea) is 0.6M and choline chloride, ChCl is 0.3M in water, was effective in improving the device characteristics. However, all three CIGS treatments improved the solar cell parameters to nearly equivalent to their original average efficiency of 10.38%.

### EXAMPLE 8

In this example, comparative device results are listed for a CIGS batch No. H020507. The results are in Table 7. Samples H020507-1,-3 and -5 were treated in aqueous thiourea solution while samples H020507-2,-4 and -6 were treated in aqueous eutectic solution. The eutectic treatment of CIGS substrates before device preparation has improved the overall device parameters resulting in enhanced photovoltaic efficiency of solar cells.

TABLE 7

| | | | | Jsc | |
|---|---|---|---|---|---|
| | | Voc | | MA/ | |
| Sample No. | Treatment | mV | FF % | cm² | Eff % |
| H020507-1 | TU, 0.6M, 60° C., 60 min | 590.5 | 69.6 | 27.74 | 11.4 |
| H020507-3 | TU, 0.6M, 60° C., 60 min | 583.6 | 68.9 | 28.48 | 11.5 |
| H020507-5 | TU, 0.6M, 60° C., 60 min | 579.6 | 70.7 | 28.4 | 11.6 |
| Average | | 584.6 | 69.7 | 28.2 | 11.5 |
| H020507-2 | EU (TU 0.6M + ChCl 0.3M) | 593.5 | 71.3 | 29.5 | 12.5 |
| H020507-4 | EU (TU 0.6M + ChCl 0.3M) | 585.3 | 73.5 | 29.18 | 12.6 |
| H020507-6 | EU (TU 0.6M + ChCl 0.3M) | 587.3 | 72 | 27.44 | 11.6 |
| Average | | 588.7 | 72.3 | 28.7 | 12.2 |

Exemplary embodiments of the present invention have been presented. The invention is not limited to these examples. These examples are presented herein for purposes of illustration, and not limitation. Alternatives (including equivalents, extensions, variations, deviations, etc., of those described herein) will be apparent to persons skilled in the relevant art(s) based on the teachings contained herein. Such alternatives fall within the scope and spirit of the invention.

All publications, patents and patent applications mentioned in this specification are indicative of the level of skill of those skilled in the art to which this invention pertains, and are herein incorporated by reference to the same extent as if each individual publication, patent or patent application was specifically and individually indicated to be incorporated by reference.

What is claimed is:

1. A method of treating a CIGS material, comprising
(a) contacting the CIGS material with an ionic solvent comprising S- or Se-containing compounds; and
(b) heating the CIGS material.

2. The method of claim 1, wherein the contacting comprises contacting the CIGS material with an ionic solvent comprising thiourea.

3. The method of claim 2, wherein the contacting comprises contacting the CIGS material with an ionic solvent wherein the concentration of thiourea is in the range of about 0.01M to about 1.00 M.

4. The method of claim 1, wherein the heating comprises heating the CIGS material to a temperature in the range of about 30° Celsius to about 85° Celsius.

5. The method of claim 1, wherein the heating comprises heating the CIGS material for about 10 minutes to about 80 minutes.

6. The method of claim 1, wherein the contacting comprises contacting the CIGS material with a 0.6 M thiourea solution, and the heating comprises heating the CIGS material to a temperature of about 60° Celsius for about 60 minutes.

7. The method of claim 1, wherein the treating dissolves impurity phases of binary oxides and selenides of copper, indium and gallium to improve photovoltaic properties of a solar cell comprising the prepared CIGS material.

8. The method of claim 1, wherein a CIGS material disposed on an electrically conducting substrate is treated.

9. A method of treating a CIGS material, comprising
(a) contacting the CIGS material with a eutectic solvent that comprises thiourea and choline chloride at a 2:1 molar ratio (thiourea:choline chloride); and
(b) heating the CIGS material.

10. The method of claim 9, wherein the contacting comprises contacting the CIGS material with a eutectic solvent that comprises 2M thiourea and 1M choline chloride.

11. The method of claim 10, wherein the heating comprises heating the CIGS material at about 80° Celsius for about 10 minutes to about 60 minutes.

12. The method of claim 9, wherein the treating dissolves impurity phases of binary oxides and selenides of copper, indium and gallium to improve photovoltaic properties of a solar cell comprising the prepared CIGS material.

13. The method of claim 9, wherein a CIGS material disposed on an electrically conducting substrate is treated.

14. The method of claim 10, wherein the contacting comprises contacting the CIGS material with an aqueous solution of 2M thiourea and 1M choline chloride, and the heating comprises heating at about 25° Celsius for about 10 minutes to about 60 minutes.

15. The method of claim 10, wherein the contacting comprises contacting the CIGS material in an aqueous solution of 0.6M thiourea and 0.3M choline chloride, and the heating comprises heating at about 60° Celsius for about 10 to about 60 minutes.

16. A CIGS material treated by the method of claim 1.

17. A CIGS material treated by the method of claim 9.

18. A method of preparing a CIGS solar cell, comprising:
(a) providing a CIGS film deposited on an electrically conducting substrate;
(b) contacting the CIGS material with a solvent comprising S- or Se-containing compounds;
(c) heating the CIGS material;
(d) preparing the CIGS material for inclusion in a solar cell; and
(e) disposing a front contact on the CIGS material to form the solar cell.

19. The method of claim 18, wherein the providing comprises disposing a CIGS semiconductor film on a glass substrate comprising an electrically conducting substrate.

20. The method of claim 18, wherein the contacting comprises contacting the CIGS material with an ionic solvent comprising thiourea.

21. The method of claim 20, wherein the contacting comprises contacting the CIGS material with thiourea in the range of about 0.01M to about 1.00 M.

22. The method of claim 18, wherein the heating comprises heating the CIGS material to a temperature in the range of about 30° Celsius to about 85° Celsius.

23. The method of claim 18, wherein the heating comprises heating the CIGS material for about 10 minutes to about 80 minutes.

24. The method of claim 18, wherein the contacting comprises the CIGS material with 0.6 M thiourea, and the heating comprises heating to a temperature of about 60° Celsius for about 60 minutes.

25. The method of claim 18, wherein the treating dissolves impurity phases of binary oxides and selenides of copper, indium and gallium.

26. The method of claim 18, wherein the contacting comprises contacting the CIGS material with a eutectic solvent that comprises thiourea and choline chloride at a 2:1 molar ratio (thiourea:choline chloride).

27. The method of claim 26, wherein the contacting comprises contacting the CIGS material with a eutectic solvent that comprises 2M thiourea and 1M choline chloride.

28. The method of claim 27, wherein the heating comprises heating the CIGS material at about 80° Celsius for about 10 minutes to about 60 minutes.

29. The method of claim 18, wherein the contacting comprises contacting the CIGS material with an aqueous solution of 2M thiourea and 1M choline chloride and the heating comprises heating the CIGS material at about 25° Celsius for about 10 minutes to about 60 minutes.

30. The method of claim 18, wherein the contacting comprises contacting the CIGS material with an aqueous solution of 0.6M thiourea and 0.3M choline chloride, and the heating comprises heating at about 60° Celsius for about 10 to about 60 minutes.

31. The method of claim 18, wherein the preparing the CIGS material for inclusion in a photovoltaic cell comprises washing and then drying the CIGS material.

32. The method of claim 18, further comprising disposing a buffer layer on the CIGS material prior to disposing the front contact.

33. The method of claim 32, wherein the disposing a buffer layer comprises disposing a layer of CdS.

34. The method of claim 18, wherein the disposing a front contact comprises disposing a transparent conductive oxide.

35. The method of claim 34, wherein the disposing a transparent conductive oxide comprises disposing ZnO.

36. A CIGS solar cell prepared by the method of claim 18.
